(19) United States
(12) Patent Application Publication
(10) Pub. No.: US 2008/0137268 A1
(43) Pub. Date: Jun. 12, 2008

(54) Personal audio player case and integrated wireless adapter

(75) Inventors: Donald R. Mayette, Vancouver, WA (US); Steve H. Jensen, Vancouver, WA (US); Wells A. Brimhall, Portland, OR (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Logitech Europe S.A., Romanel-sur-Morges (CH)

(21) Appl. No.: 11/650,338

(22) Filed: Jan. 4, 2007

Related U.S. Application Data
(60) Provisional application No. 60/756,600, filed on Jan. 4, 2006.

(51) Int. Cl. H04R 1/10; H05K 5/00

(52) U.S. Cl. 361/679; 381/374

(57) ABSTRACT

An integrated personal audio player case and wireless adapter includes a rigid main body and a rigid closable top that are sized to receive and encase a selected personal audio player, such as a digital personal audio player having a user control structure and at least one output connector for audio content. The top includes an open aperture through which a user can access and operate the user control structure. An integrated wireless adapter is encased within the main body for providing a localized wireless communication channel to a wireless device, such as headphones. At least one electrical connector connects to the at least one output connector to deliver audio content from the selected personal audio player to the integrated wireless adapter.

### BACKGROUND AND SUMMARY OF THE INVENTION

Personal audio players are well known and conventionally have played audio content from any of a variety of formats including radio broadcasts, cassette tapes, compact discs (CDs). More recently, digital personal audio players have played digital audio content that is stored in a digital medium such as a memory circuit (e.g., flash memory) or a disk drive. Examples of such digital personal audio players include the iPod® players available from Apple Computer Company, including the original iPod®, the iPod® mini, and the iPod® nano.

FIG. 11 is a multi-view illustration of an iPod® nano player 10, which includes a front face 12 with a display screen 14 and a user control structure 16. One edge includes a dock connector 18 for connecting the player to a dock or other units to recharge the player, to load audio content to or from the player, to manage the audio content on the player, etc. An audio output connector 20 provides audio output for audio content being played on player 10. Typically, a user plugs wired headphones (not shown) into output connector 20 to listen to the audio content.

As an alternative to conventional wired headphones, users listen to the audio content with wireless headphones, such as the Freepulse™ Wireless Headphones, which are available from Logitech Corporation. FIG. 12 is an illustration of a wireless headphone system 30, which includes wireless headphones 32 and a wireless adapter 34. Wireless headphones 32 include integrated audio player controls 36 with which a user can adjust volume, play, pause, select tracks, etc. Wireless headphones 32 and wireless adapter 34 separately include batteries (not shown) for power and communicate with each other over a localized wireless connection, such as a Bluetooth standard connection. Wireless adapter 34 includes a plug 38 that plugs into output connector 20 of a personal audio player, such as iPod® nano player 10. It will be appreciated that wireless headphone system 30 may be used with any type of personal audio player, including conventional (non-digital) personal audio players and digital personal audio players.

Such a wireless adapter is external to the personal audio player and is connected to it mainly by an electrical connector, such as a 3.5 mm stereo audio jack. While adequate for some uses, such a physical coupling can be less than optimal for providing a physically secure coupling between the wireless adapter and the personal audio player. During some physical activity such as jogging, for example, the electrical connector may not be adequate to hold the wireless adapter and the personal audio player securely together.

Accordingly, the present invention provides an integrated personal audio player case and wireless adapter. In one implementation, the integrated case and wireless adapter includes a rigid main body and a rigid closable top that are sized to receive and encase a selected personal audio player, such as a digital personal audio player having a user control structure and at least one output connector for audio content. In this implementation, the top includes an open aperture through which a user can access and operate the user control structure.

An integrated wireless adapter is encased within the main body for providing a localized wireless communication channel to a wireless device. At least one electrical connector connects to the at least one output connector to deliver audio content from the selected personal audio player to the integrated wireless adapter.

Additional objects and advantages of the present invention will be apparent from the detailed description of the preferred embodiment thereof, which proceeds with reference to the accompanying drawings.

### BRIEF DESCRIPTION OF THE DRAWINGS

FIG. 1 is a front perspective view of an integrated personal audio player case and wireless adapter with its top in a closed position;

FIG. 2 is a front view thereof;

FIG. 3 is a left side view thereof;

FIG. 4 is a right side view thereof;

FIG. 5 is a top view thereof;

FIG. 6 is a bottom view thereof;

FIG. 7 is a front perspective view of the integrated personal audio player case and wireless adapter of FIG. 1 showing its top in an open position;

FIG. 8 is a front view thereof;

FIG. 9 is a left side view thereof; and,

FIG. 10 is a right side view thereof.

### DETAILED DESCRIPTION OF THE INVENTION

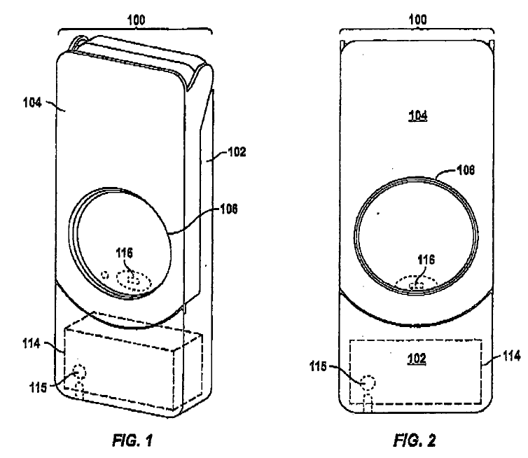

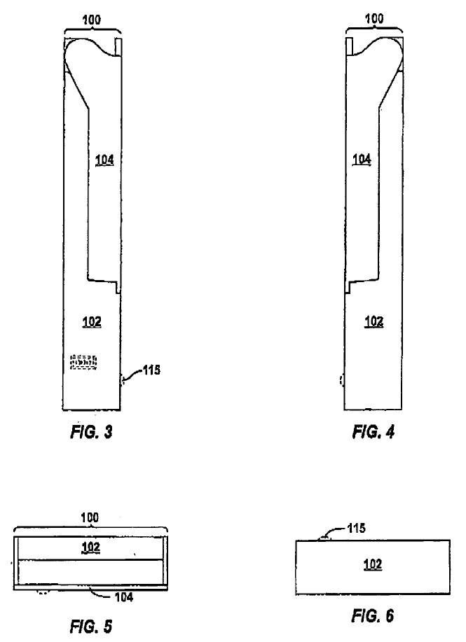

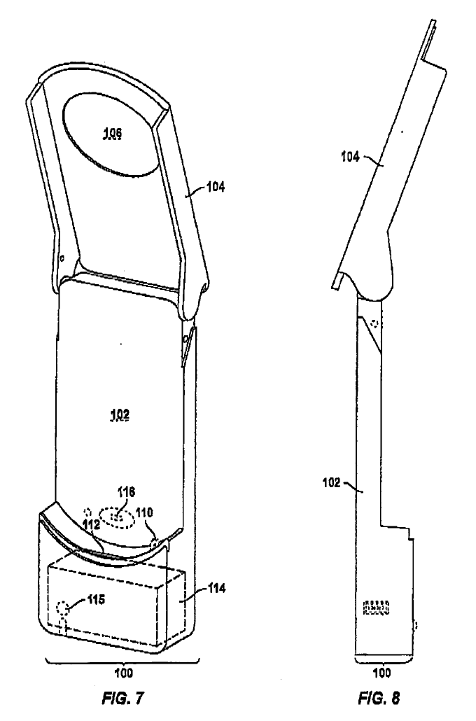

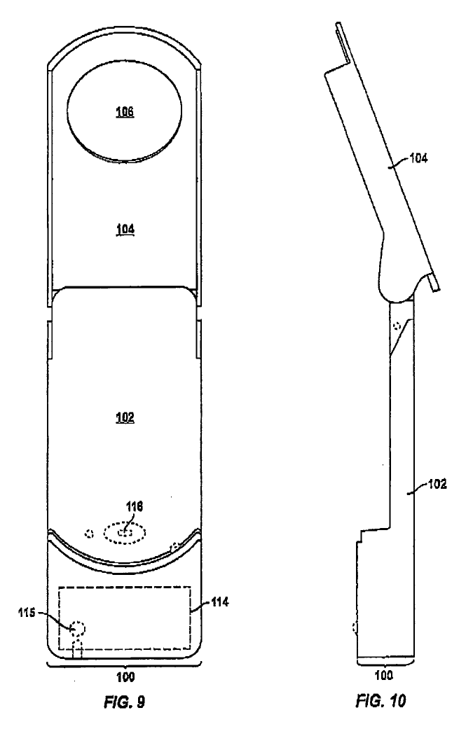

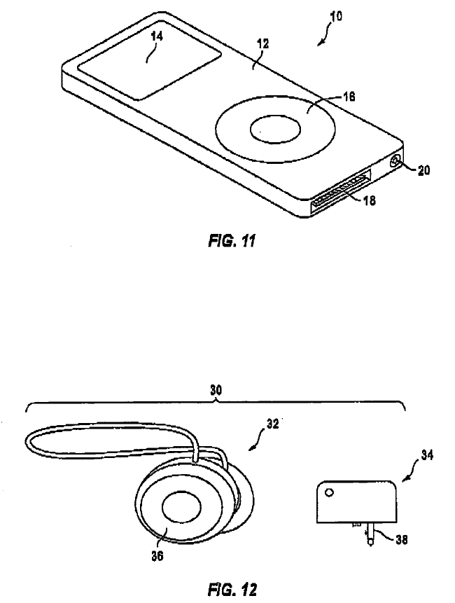

FIGS. 1-10 illustrate one implementation of an integrated personal audio player case and wireless adapter 100 in connection with the present invention, sometimes referred to as integrated player case and adapter 100. Integrated player case and adapter 100 includes a rigid main body 102 and a rigid closable flip-top 102. FIGS. 1-4 show flip-top 104 in a closed position, and FIGS. 7-10 show flip-top 104 in an open position.

Integrated player case and adapter 100 is sized to receive and encase a selected personal audio player. In the illustrated implementation, integrated player case and adapter 100 is sized and configured to receive and encase an iPod® nano audio player 10 (FIG. 11). It will be appreciated that an integrated player case and adapter of the present invention could be sized and configured to receive and encase any selected personal audio player, including any iPod® brand players or any other digital personal audio players, as well as any non-digital personal audio players.

Flip-top 104 includes an open aperture 106 through which a user can access and operate user control structure 16 of audio player 10 (FIG. 11). Flip-top 104 is formed of a clear plastic to allow a user to see player display screen 14 or, alternatively, could include a clear window or an aperture in an otherwise opaque flip-top. In the illustrated implementation, open aperture 106 is sized and configured to match user control structure 16 of iPod® nano player 10 (FIG. 11). It will be appreciated, however, that the open aperture could be sized and configured to match the user control structure of any selected personal audio player.

Integrated player case and adapter 100 includes an audio connector 110 (FIG. 7) and a multi-pin dock connector 112 (FIG. 7) that are coupled to a wireless adapter 114 (shown in outline) encased within main body 102. Audio connector 110 and multi-pin dock connector 112 are configured and positioned to match and connect to the corresponding dock connector 18 and audio output connector 20 of the selected player 10. Wireless adapter 114 provides a localized wireless communication channel (e.g., Bluetooth standard) with wireless headphones, such as Logitech® Wireless Headphones for iPod® (FIG. 12), or other devices. A wireless channel indicator light 115 indicates whether wireless adapter 114 is on and whether or not it is operating normally.

Rigid main body 102 and rigid closable flip-top 102 cooperate to provide a protective enclosure for audio player 10 and also to provide a secure attachment between audio player 10 and connectors 110 and 112. Attaching a wireless adapter to an audio player just by means of an electrical connection, without the enveloping casing of the present invention, can allow the wireless adapter to be inadvertently disconnected from the audio player during normal usage. Such disconnections are highly disruptive for users.

A user-operable remote/local control switch 116 allows a user to select whether audio player 10 retains local control of the audio playback, as in normal operation, or is controlled by the remote wireless device (e.g., wireless headphones). With switch 116 in the remote control mode, wireless adapter 116 uses multi-pin dock connector 112 to receive “line out” audio content from audio player 10, for transmission to the remote wireless device, and to deliver to audio player 10 remote control signals (e.g., play, pause, skip, etc.) received from the remote wireless device (e.g., wireless headphones 32, FIG. 12). In this remote control mode the remote wireless device (e.g., wireless headphones 32, FIG. 12) functions as the user-operable controller for the audio playback.

With switch 116 in the local control mode, wireless adapter 116 uses audio connector 110 to receive audio content from audio player 10. In this local control mode the remote wireless device (e.g., wireless speakers or receiver, not shown) plays back audio content according to the user's control of the audio player 10, including volume, play, stop, skip, etc. This local control mode allows a user to control playback at a remote device (e.g., speakers, receiver, etc.) by manipulation of the control structure 16 of the audio player 10. In this local control mode, audio player 10 in combination with integrated player case and adapter 100 appears to function like a “remote control” for the remote device (e.g., speakers, receiver, etc.), even though the control functions are executed on the local audio player 10.

The present invention is directed to a case that contains a personal audio player to provide a secure connection to an integral wireless adapter. Integrated player case and adapter 100 is described as having a rigid body 102 and a flip-top 104. It will be appreciated, however, that the present invention would encompass other implementations of an integrated player case and adapter including, for example, main bodies that are pliable, rather than rigid. Also, other implementations of an integrated player case and adapter according to the present invention may include tops, enclosures, clamps, grips, bands, etc., that secure a personal audio player within a main body without a flip-top 104. Such alternative tops, enclosures, clamps, grips, bands, etc. may cooperate with the main body to substantially enclose a personal audio player, as does flip-top 104, or may function to secure the periphery of a personal audio player to provide a secure physical coupling between it and the integral wireless adapter.

In view of the many possible embodiments to which the principles of our invention may be applied, it should be recognized that the detailed embodiments are illustrative only and should not be taken as limiting the scope of our invention. Rather, the invention includes all such embodiments as may come within the scope and spirit of the following claims and equivalents thereto.

1. An integrated personal audio player case and wireless adapter, comprising:
a rigid main body and a rigid closable top that are is sized to receive and encase a selected personal audio player having a user control structure and at least one output connector for audio content, the top including an open aperture through which a user can access and operate the user control structure;
an integrated wireless adapter encased within the main body for providing a localized wireless communication channel to a wireless device; and
at least one electrical connector for connecting to the at least one output connector to deliver audio content from the selected personal audio player to the integrated wireless adapter.

2. The integrated personal audio player case and wireless adapter of claim 1 in which the rigid closable top is a flip-top.

3. The integrated personal audio player case and wireless adapter of claim 1 in which the at least one output connector of the selected personal audio player includes a dock connector and a separate audio output connector and in which the at least one electrical connector includes a dock electrical connector and a separate audio electrical connector that are configured and positioned to match and connect to the respective dock connector and separate audio output connector of the selected personal audio player.

4. The integrated personal audio player case and wireless adapter of claim 3 further comprising a user-operable remote/local control switch that allows a user to select whether the selected personal audio player retains local control of audio playback or is controlled by the remote wireless device.

5. The integrated personal audio player case and wireless adapter of claim 1 in which the selected personal audio player is a digital personal audio player.

6. The integrated personal audio player case and wireless adapter of claim 1 in which the wireless device is headphones.

7. An integrated personal audio player case and wireless adapter, comprising:
a main body that is sized to receive and encase a selected personal audio player having a user control structure and at least one output connector for audio content, the body allowing a user to access and operate the user control structure;
an integrated wireless adapter contained within the main body for providing a localized wireless communication channel to a wireless device; and
at least one electrical connector for connecting to the at least one output connector to deliver audio content from the selected personal audio player to the integrated wireless adapter.

8. The integrated personal audio player case and wireless adapter of claim 1 further including a top that is closeable to hold the personal audio player within the main body.

9. The integrated personal audio player case and wireless adapter of claim 8 in which the top cooperates with the main body to completely encompass the personal audio player.

10. The integrated personal audio player case and wireless adapter of claim 8 in which the top is rigid.

11. The integrated personal audio player case and wireless adapter of claim 8 in which the top is pivotably closes to hold the personal audio player within the main body.

12. The integrated personal audio player case and wireless adapter of claim 8 in which the top covers the user control structure of the personal audio player and the top includes an access panel in the top where a user can access the user control structure of the personal audio player.

13. The integrated personal audio player case and wireless adapter of claim 7 further including an access panel where a user can access the user control structure of the personal audio player.

14. The integrated personal audio player case and wireless adapter of claim 7 in which the at least one output connector of the selected personal audio player includes a dock connector and a separate audio output connector and in which the at least one electrical connector includes a dock electrical connector and a separate audio electrical connector that are configured and positioned to match and connect to the respective dock connector and separate audio output connector of the selected personal audio player.

15. The integrated personal audio player case and wireless adapter of claim 14 further comprising a user-operable remote/local control that allows a user to select whether the selected personal audio player retains local control of audio playback or is controlled by the remote wireless device.

16. The integrated personal audio player case and wireless adapter of claim 7 in which the selected personal audio player is a digital personal audio player.

17. The integrated personal audio player case and wireless adapter of claim 7 in which the wireless device is headphones.
